(19) United States
(12) Patent Application Publication
(10) Pub. No.: US 2009/0250808 A1
(43) Pub. Date: Oct. 8, 2009

(54) RELIABILITY IMPROVEMENT IN A COMPOUND SEMICONDUCTOR MMIC

(75) Inventors: Randall D. Lewis, Glen Rock, PA (US); Harlan Carl Cramer, Columbia, MD (US)

Correspondence Address: MARSTELLER & ASSOCIATES, P. C., P. O. BOX 803302, DALLAS, TX, 75380-3302, US

(73) Assignee: NORTHROP GRUMMAN SYSTEMS CORPORATION, Los Angeles, CA (US)

(21) Appl. No.: 12/416,711

(22) Filed: Apr. 1, 2009

Related U.S. Application Data
(60) Provisional application No. 61/043,087, filed on Apr. 7, 2008.

(51) Int. Cl. H01L 23/34; H01L 21/50

(52) U.S. Cl. 257/713; 438/106; 257/E23.08; 257/E21.499

(57) ABSTRACT

A semiconductor package (M) includes a semiconductor substrate layer (100) having a first side or upper surface (120) and a second side or lower surface or backplane (104) opposite the first side (120). A heat producing active area (102) is formed associated with the first side (120) of the semiconductor substrate layer (100). A die attachment member (106) is formed in contact with the second side (104) of the semiconductor substrate layer (100) and extends over less than all of the second side (104) of the semiconductor substrate layer (100). The die attachment material (106) is essentially uniformly disposed opposite of the heat producing area (102) with relation to the semiconductor substrate layer (100).

### CROSS REFERENCE TO RELATED APPLICATIONS

This application claims the benefit of U.S. Provisional Application Ser. No. 61043087, filed Apr. 7, 2008, entitled RELIABILITY IMPROVEMENT IN A COMPOUND SEMICONDUCTOR MMIC.

### BACKGROUND OF THE INVENTION

1. Technical Field

The invention relates to the field of semiconductor devices, and more particularly to pulsed, high-powered discrete devices and monolithic microwave integrated circuits (MMICs).

2. Background Art

Thermo-mechanical metal fatigue in compound semiconductors (GaN, GaAs, and SiC, for example) has been found to occur in pulsed, high-powered discrete devices and monolithic microwave integrated circuits (MMICs) that are used in known active electronically steered arrays (AESAs). The pulsed operation of the compound semiconductor devices has been shown to result in thermo-mechanical fatigue and early, wear-out failure of several compound semiconductor device technologies. Often, systems applications require tens of billions of pulsed cycles to be endured by the semiconductor device during an AESA system lifetime, and the thermo-mechanical damage from each pulse results in additional cumulative damage to the device.

Compound semiconductor MMICs have been found to exhibit a thermo-mechanical failure mechanism of the die attachment resulting in early life failure of the devices.

The die attachment of a high-powered compound semiconductor device performs three primary functions: First, it provides low resistance electrical connection from the back of the die to the device package. Second, it provides thermal path for the heat to flow from the semiconductor channel (or junction) through the die, the die attachment, the substrate, and out to a heat-sink of some type. Finally, the die attachment provides mechanical stability for the die (it physically hold it in place). Maintaining all three of these functions is necessary for the device to continue functioning reliably.

An expression, called the Coffin-Manson relation, has been developed to relate the number of thermal cycles a die attachment can withstand before failure to the properties of the system.

$$Nf ∝ {γ}^{m} ( \frac{2 * t}{L * Δ CTE * Δ T} )$$

where
γ=shear strain for failure
m=constant dependent on the material
L=diagonal length of the die
t=die-attach material thickness

Known compound semiconductors subjected to accelerated life testing (ALT) have manifested this thermo-mechanical fatigue both in the top metallization of the device and also in the metallization that forms the die attachment to the substrate. The failure in either metallization system has been shown to result in device failure, and the one that fails first is generally the life-limiting element. In some cases, the top metallization may fail first. In others, it may be the die attachment that has failed first.

Temperature excursions from pulsed applications may result in cyclical thermo-mechanical stress caused by the coefficient of thermal expansion (CTE) mismatch between the semiconductor material and the metals used for the die attachment, or the CTE mismatch between the die attachment metals themselves. After many thousands, millions, or even billions of pulsed power cycles, the die attachment may develop discontinuities and the device fails from an over-temperature event as the heat can no longer be removed from the die.

Failure has also been shown to be indicated by severe degradation of device electrical parameters, most notably drain-to-source resistance (Rds). The CTE mismatch cannot be avoided in some material systems, leaving the only option to reduce the power output which lowers the thermo-mechanical strain in the die attachment but also lowers device performance, an undesirable result. An example of a pulsed thermo-mechanical die attachment failure is shown in FIG. 1.

Current and future compound semiconductors (such as higher power GaAs, SiC, and GaN) technologies are pioneering the use of higher power supply voltages and drain currents and are resulting in higher die attachment thermal excursions, making thermo-mechanical fatigue an ever increasing reliability concern. For example, the Defense Advanced Research Projects Agency (DARPA) Wide Bandgap Initiative is targeting GaN power densities of 5.6 watts/mm of gate periphery. Testing has shown that devices with silicon carbide substrates (GaN has a silicon carbide substrate) may fail from die attachment thermo-mechanical fatigue when operated pulsed at 5.6 watts/mm (or lower).

It is also known that voids introduced into the die-attach materials can significantly reduce the number of thermal cycles before failure. Such voids cause localized stress in the die-attach material during thermal cycles since the void is not a good thermal conductor.

While the above cited references introduce and disclose a number of noteworthy advances and technological improvements within the art, none completely fulfills the specific objectives achieved by this invention.

### DISCLOSURE OF INVENTION

In accordance with the present invention, a semiconductor package includes a semiconductor substrate layer having a first side and a second side opposite the first side. A heat producing active area is formed associated with the first side of the semiconductor substrate layer. A die attachment package is formed in contact with the second side of the semiconductor substrate layer and extends over less than all of the second side of the semiconductor substrate layer. The die attachment material is essentially uniformly disposed opposite of the active area with relation to the semiconductor substrate layer.

Known manufacturing methods use 100% of the MMIC area to attach the die to the substrate. The present invention of patterning (reducing the area) of the backside metallization of the die to reduce the die attachment area is not believed to be known and addresses thermo-mechanical fatigue which was a previously unknown failure mechanism in compound semiconductor MMIC die attachment. Further, known manufacturing methods utilize 100% of the back of the MMIC for die attachment which will in reality reduce device reliability by increasing the mechanical strain in the die attachment during pulsed operation.

A problem solved by the present invention is one of device lifetime—known manufacturing techniques are vulnerable to wearout of the die attachment.

The present invention also provides a technique to increase the life of the die attachment systems when thermo-mechanical metal fatigue occurs in the die attachment metallization first.

The present invention significantly reduces the mechanical strain by reducing the die attachment area of the MMIC (the larger the die attachment area, the higher the mechanical strain), keeping only that portion that is needed for mechanical stability, electrical conductivity, and thermal dissipation of the active device. This yields a device with an effectively smaller die attachment area that results in increasing the lifetime (reliability) of the device without compromising on device performance. It will allow devices that are limited by die attachment fatigue life to be reliably operated at higher power levels for longer periods of time, increasing AESA and overall radar system performance.

Another purpose of the present invention is to increase the reliability of pulsed, high-powered compound semiconductor MMICs (such as higher power GaAs, SiC, and GaN MMICs) by reducing the die attachment area which results in reduced thermo-mechanical fatigue of the die attachment.

These and other objects, advantages and preferred features of this invention will be apparent from the following description taken with reference to the accompanying drawings, wherein is shown the preferred embodiments of the invention.

### BRIEF DESCRIPTION OF DRAWINGS

A more particular description of the invention briefly summarized above is available from the exemplary embodiments illustrated in the drawing and discussed in further detail below. Through this reference, it can be seen how the above cited features, as well as others that will become apparent, are obtained and can be understood in detail. The drawings nevertheless illustrate only typical, preferred embodiments of the invention and are not to be considered limiting of its scope as the invention may admit to other equally effective embodiments.

FIG. 1 is a depiction of a coefficient of thermal expansion (CTE) caused thermo-mechanical die attach fatigue failure in a semiconductor device when the device has been pulsed.

FIG. 2 is an IR image of an operating MMIC.

FIG. 3 is the IR image of FIG. 2 with boxes annotating areas of patterned die attachment.

FIG. 4 is a depiction of an exemplary patterned die attachment of the print invention.

FIG. 5 is a cross-sectional bottom view taken through lines 4-4 of FIG. 4.

### MODE(S) FOR CARRYING OUT THE INVENTION

So that the manner in which the above recited features, advantages and objects of the present invention are attained can be understood in detail, more particular description of the invention, briefly summarized above, may be had by reference to the embodiment thereof that is illustrated in the appended drawings. In all the drawings, identical numbers represent the same elements.

A semiconductor package M includes a semiconductor substrate layer 100 having a first side or upper surface 120 and a second side or lower surface or backplane 104 opposite the first side 120. A heat producing or active area 102 is formed associated with the first side 120 of the semiconductor substrate layer 100. A die attachment member 106 is formed in contact with the second side 104 of the semiconductor substrate layer 100 and extends over less than all of the second side 104 of the semiconductor substrate layer 100. The die attachment material 106 is essentially uniformly disposed opposite of the heat producing area 102 with relation to the semiconductor substrate layer 100.

The die attachment area under the compound semiconductor die utilizes 100% of the area (typically the die is rectangular in shape). To achieve the required mechanical strength, far less than 100% of the die area is required (very little in fact, less than 10% would be sufficient). To achieve a low-resistance connection, only part of the connection is required. Since the heat generated from the channel or junction of the device spreads downward at approximately a 45 degree angle, the required die attachment is a function of the active or heat producing area and the thickness of the die. Again, this is a small portion of the total area of a compound semiconductor MMIC as much of the MMIC area is made up of non or very low-power dissipating structures such as inductors, transmission lines, capacitors, and biasing resistors.

The fact that much of the die attachment area of a compound semiconductor MMIC die attachment area is not functionally necessary forms the basis of the present invention, that is, that there is an opportunity to reduce the area of the MMIC die attachment without compromising any device performance while at the same time increasing the die attachment fatigue life of the device (increasing useful life). This will allow MMICs to operate at higher powers for longer period of times, increasing system power levels from limits imposed by die attachment fatigue life.

Thermo-mechanical fatigue in high-powered silicon semiconductors has been more widely studied than that of compound semiconductor MMICs. Die attachment fatigue of several types of high-powered silicon devices, including Insulated Gate Bipolar Transistors (IGBTs) and power metal-oxide-semiconductor field-effect transistors (MOSFETs), is known. It has been found that a relationship exists between die attachment area, power dissipation, and die attachment fatigue. Some silicon power device manufacturers provide reliability data relating number of power cycles to device life and explicitly state that the curves hold true for a given die attachment area and any die attachment area that is smaller. A larger die attachment area would require a more conservative curve with lower life times. This is another key point of the present invention. It is well known that with high powered silicon devices, that reducing the area of die attachment increases device life time. This is because there is a relationship between mechanical stress and the size of the die attachment area—the larger the area, the higher the stress. However, unlike compound semiconductor MMICs, silicon power devices utilize almost all of their die area for the active, heat generating device, so the opportunity to significantly reduce the die attachment area is not feasible.

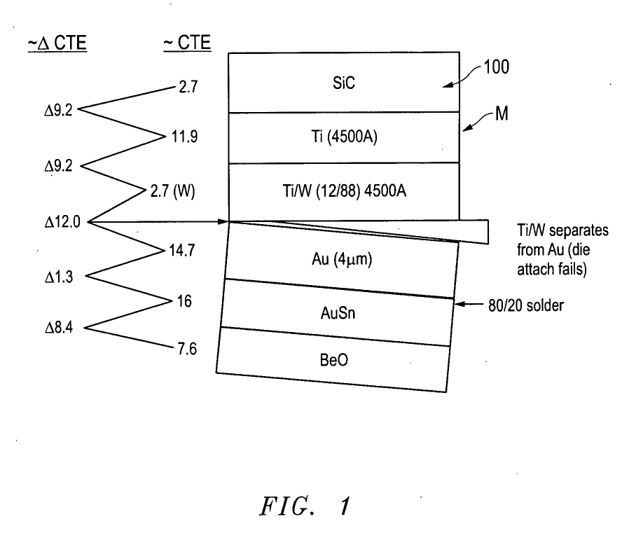

With regard particularly to FIG. 1, the semiconductor package M refers to everything above the AuSn 80/20 solder layer, and the semiconductor chip or substrate layer 100 refers to die layer marked with “SiC.”

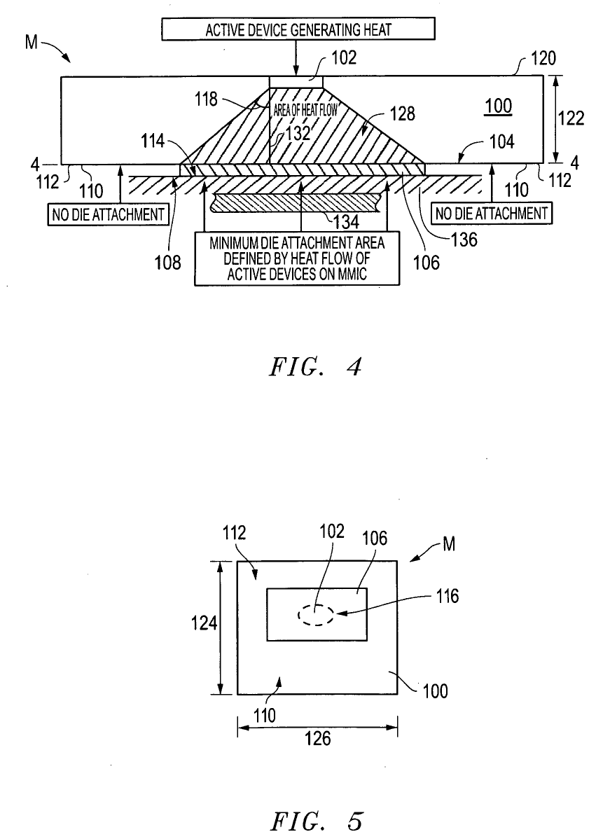

That being said, in accordance with an exemplary embodiment of the present invention, FIG. 4 places a patterned die attachment 106 on the bottom 104 of a semiconductor chip or substrate layer 100, such as a MMIC type device. The same principles described in conjunction with a GaAs amplifier MMIC may be applied to other devices. Currently, known MMICs or similar semiconductor packages M have 100% of the area of the backside or underside surface 112 of the MMIC ground plane layer 104 mating with the attached die material or support member 106 being covered with die attachment metal 114 (except for vias to the topside 120 of the MMIC 100, if they exist).

The present invention has die attachment material 106 attached to or formed on only on those limited areas 116 of the bottom 104 of the MMIC chip 100 that are under active or heat producing devices 102 on the upper surface 120 of the MMIC chip 100. The minimum die attachment area 116 will be defined by the area that spreads at a selected angle 118, such as 45 degrees measured with respect to an orthogonal line or axis 132 from the upper surface 120, from the active devices 102 on the topside 120 of the MMIC chip or layer 100 through the thickness 122 of MMIC material layer 100 to the die attached material 106. An example is shown in FIG. 4.

The active or heat producing devices 102 on the upper surface 120 of the MMIC chip 100 can be one or more active devices such as a transistor or the like, that produce heat, or some other heat producing type device such as a resistor.

The thermal diffusion path 128 representing the heat generated by the active device 102 on the upper surface 120 diffuses through the semiconductor substrate layer 100 in a rather uniform manner radiating from the active device 102. Such possible path 128 is shown as being a shaded area in FIG. 4.

FIG. 5 depicts an alternative embodiment of the present invention in which the die attachment material layer 106 is attached to only a portion of the width 124 and length 126 of the underside 112 of the MMIC chip layer 100. A portion or area 110 of the underside surface 112 has no die attachment material 106 in contact.

Shown in phantom in FIG. 5 is the active FET device 102 on the upper surface 120 that is immediately above and centrally located relative to the limited or patterned die attachment area 116.

The semiconductor device M including the semiconductor layer 100 and the die attachment material layer or member 106 may be optionally formed with a package base layer or member 108.

A patterned die attachment of the present invention used in the manufacture of a MMIC device M is easily detectable with a simple, non-destructive x-ray inspection or a non-destructive acoustic microscope examination.

The angle 118 chosen for the calculation of the size of the die attachment area 116 can vary based on the thermal diffusion properties of the MMIC chip material 100. The size and shape of the die attachment area 116 may be determined with regard to the shape of the active device 102, the selected angle chosen 118, and the thickness of the MMIC layer 122 (or alternatively, the thickness of the MMIC layer 122 taking into account the thickness of the active device 102).

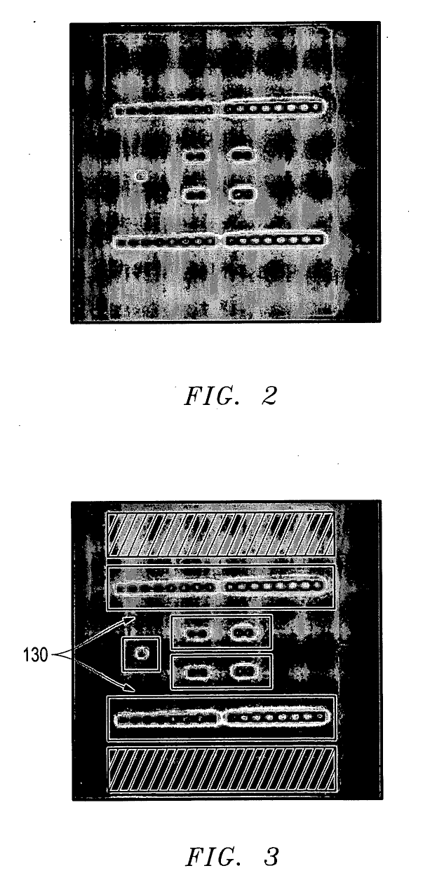

FIG. 2 depicts an IR image of an operating MMIC device M. Highlighted (hot) areas show active FETs. The rest of the MMIC structure 100 dissipates no heat. The die attachment area 116 is 100% of the MMIC area 110.

FIG. 3 depicts an annotated IR image of FIG. 2 with boxes 130 showing areas of patterned die attachment 116. Heat is still as effectively removed from the active FETs 102. The cross-sectional area is effectively reduced thereby increasing time to cycle fatigue failure (improving reliability). Attachment added at the ends reduces Rds and increases mechanical strength.

The present invention uses a patterned die attachment on the backside metallization of the die attached material 106 that reduces the die attachment area 116 while maintaining electrical conductivity, providing a heat flow path, and providing mechanical stability. The present invention is targeted at reducing thermo-mechanical strain introduced by high powered, pulsed operation of a compound semiconductor MMIC device M. The strain is reduced by reducing die attachment cross-sectional area during pulsed operation. The same materials are used, but the device processing and final structure have not heretofore been disclosed.

Patterning the die attachment in accordance with the present invention by making it dimensionally smaller lowers the strain magnitude in the joint. This is believed to be one reason why adding solder on the ends will not result in increased thermo-mechanical fatigue, but can reduce Rds and increase mechanical strength. Another reason is believed that those areas will see very little change in temperature so they will not get fatigued as quickly.

The patterning for the present invention may be done to the back of a semiconductor during wafer fabrication, but may also be done during an assembly step. The metals, such as Titanium (Ti). TiTungsten (TiW), gold, and the like may be deposited during wafer fabrication. The gold-tin (AuSn) or other types of solder may also be applied during assembly.

Specific types of known compound semiconductor MMIC devices have been found to wearout prematurely from thermo-mechanical fatigue of the die attachment. Well established modeling of stress/strain shows that reducing the cross-sectional area of a device reduces the mechanical strain.

In general, the present invention is useful with a semiconductor device M that is conducting heat in such a way that less than 100% of the second side 104 is conducting heat away from the semiconductor substrate 100 to packaging materials 134 surrounding or containing the semiconductor substrate layer 100. An example of such a device is a semiconductor MMIC.

Alternatively, the semiconductor substrate layer 100 may be attached to packaging materials 134 with a metallurgical die attachment 136 that is subject to thermo-mechanical fatigue during pulsed operation of the semiconductor device. The thermo-mechanical fatigue failure mechanism generally has both power dissipation and pulsed operation to manifest. Since many power devices are pulsed (in radar, for example), this covers a large number of semiconductor type devices.

The strain theory for devices with a patterned die attachment have been validated in existing die attachment testing.

A good ground-plane for a MMIC type or similar semiconductor device may be a requirement at some frequencies. In an additional embodiment, the patterned die attachment system of the present invention metal may be formed or placed in areas that do not have a die attachment. Such placed metal may act as a ground-plane, but not form a die attachment.

The foregoing disclosure and description of the invention are illustrative and explanatory thereof, and various changes in the size, shape and materials, as well as in the details of the illustrated construction may be made without departing from the spirit of the invention.

1. A semiconductor package comprising:
a semiconductor substrate layer having a first side and a second side opposite the first side; a heat producing area being formed associated with the first side of the semiconductor substrate layer; and,
a die attachment member being formed in contact with the second side of the semiconductor substrate layer extending over less than all of the second side of the semiconductor substrate layer and essentially uniformly disposed opposite of the heat producing area with relation to the semiconductor substrate layer.

2. The invention of claim 1 wherein the semiconductor substrate layer is a MMIC type device.

3. The invention of claim 1 wherein the heat producing area includes an active semiconductor type device.

4. The invention of claim 1 wherein the semiconductor substrate layer conducts heat in a manner such that less than 100% of the second side is conducting heat away from the semiconductor substrate layer.

5. The invention of claim 1 wherein the semiconductor substrate layer is attached to packaging materials with a metallurgical die attachment that is subject to thermo-mechanical fatigue during pulsed operation.

6. A method for forming a semiconductor package of the type including a semiconductor substrate layer having a first side and a second side opposite the first side; a heat producing area being formed associated with the first side of the semiconductor substrate layer comprising the steps of:
forming a die attachment member in contact with the second side of the semiconductor substrate layer extending over less than all of the second side of the semiconductor substrate layer and essentially uniformly disposed opposite of the active area with relation to the semiconductor substrate layer.

7. The method of claim 6 wherein the semiconductor substrate layer is a MMIC type device.

8. The method of claim 6 wherein the semiconductor substrate layer conducts heat in a manner such that less than 100% of the second side is conducting heat away from the semiconductor substrate layer.

9. The method of claim 6 wherein the semiconductor substrate layer is attached to packaging materials with a metallurgical die attachment that is subject to thermo-mechanical fatigue during pulsed operation.
